(19) United States
(12) Patent Application Publication
(10) Pub. No.: US 2013/0248228 A1
(43) Pub. Date: Sep. 26, 2013

(54) FLEXIBLE PRINT CIRCUIT BONDING STRUCTURE OF AN ELECTRONIC DEVICE

(71) Applicants: Chih-Yu LIU, Hsinchu (TW); Jeng-Maw CHIOU, Hsinchu (TW)

(72) Inventors: Chih-Yu LIU, Hsinchu (TW); Jeng-Maw CHIOU, Hsinchu (TW)

(21) Appl. No.: 13/607,047

(22) Filed: Sep. 7, 2012

(30) Foreign Application Priority Data
Mar. 22, 2012 (CN) 201210083461.0

(51) Int. Cl. H05K 1/09; H05K 1/02

(52) U.S. Cl. 174/254

(57) ABSTRACT

A flexible print circuit bonding structure of an electronic device is provided. The electronic device has a viewing area, a tracing area and a bonding area, wherein the tracing area is disposed between the viewing area and the bonding area. The flexible print circuit bonding structure includes a substrate. A transparent conductive layer is disposed on the substrate and extends from the tracing area to the bonding area. A metal trace layer is disposed on the transparent conductive layer at the tracing area, but does not extend to the bonding area. An anisotropic conductive film is disposed on the transparent conductive layer at the bonding area and directly contacts the transparent conductive layer. Then, a flexible print circuit is bonded to the anisotropic conductive film.

### CROSS REFERENCE TO RELATED APPLICATIONS

This Application claims priority of the People's Republic of China Patent Application No. 201210083461.0, filed on Mar. 22, 2012, the entirety of which is incorporated by reference herein.

### BACKGROUND OF THE INVENTION

1. Field of the Invention

The present invention relates to a flexible print circuit bonding structure of an electronic device, and in particular relates to a flexible print circuit bonding structure without metal contact.

2. Description of the Related Art

In general, metal traces are formed at an area outside an active area of an electronic device and electrically connected to electronic elements in the active area. In conventional electronic devices, the metal traces further extend to an outer bonding area of the electronic device to make a flexible print circuit (FPC) bonded with the metal traces through an anisotropic conductive film (ACF). Thus, an electrical signal provided from the flexible print circuit (FPC) is delivered to the electronic elements at the active area of the electronic device.

In the flexible print circuit bonding structure of conventional electronic devices, the anisotropic conductive film (ACF) directly contacts the metal traces. However, the bonding strength between the material of the metal traces and the material of the anisotropic conductive film (ACF) is not good. Therefore, the flexible print circuit (FPC) is easy delaminated from the metal traces. It causes the flexible print circuit bonding structures of conventional electronic devices to have issues of poor reliability.

In addition, a metal trace formed by a printing process has a greater thickness than that of a metal trace formed by other processes. When the metal traces formed by a printing process are bonded with a flexible print circuit (FPC) through an anisotropic conductive film (ACF), the metal traces are easy leveled due to the properties of the material of the metal traces. It causes a short issue occurring between the metal traces at the bonding area. Thus, it contributes to the flexible print circuit bonding structure of the conventional electronic devices having poor reliability.

### BRIEF SUMMARY OF THE INVENTION

Therefore, the embodiments of the invention provide flexible print circuit bonding structures of an electronic device. The flexible print circuit bonding structures have no metal contact at a bonding area of the electronic device. In other words, metal traces formed at a tracing area of the electronic device do not extend to a bonding area of the electronic device. A flexible print circuit (FPC) is bonded with a transparent conductive layer at the bonding area through an anisotropic conductive film (ACF). Therefore, the reliability issue of the flexible print circuit bonding structures of the conventional electronic device caused by a poor bonding strength between the anisotropic conductive film (ACF) and metal contacts of the metal traces is overcome.

Moreover, according to the embodiments of the invention, the metal traces can be formed by a printing process and the above-mentioned reliability issue of the flexible print circuit bonding structures of the conventional electronic device is overcome.

According to an illustrative embodiment, flexible print circuit bonding structures of an electronic device is provided. The electronic device has a viewing area, a tracing area and a bonding area, wherein the tracing area is disposed between the viewing area and the bonding area. The flexible print circuit bonding structure comprises a substrate having a first surface and a second surface opposite to the first surface. A transparent conductive layer is disposed on the first surface of the substrate and extends from the tracing area to the bonding area. A metal trace layer is disposed on the transparent conductive layer at the tracing area, but does not extend to the bonding area. An anisotropic conductive film is disposed on the transparent conductive layer at the bonding area, wherein the anisotropic conductive film directly contacts the transparent conductive layer. Further, a flexible print circuit is bonded to the anisotropic conductive film.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 shows an illustrative top view of a portion of an electronic device containing a flexible print circuit bonding structure according to an embodiment of the invention;

FIG. 2 shows an illustrative cross section of a portion of an electronic device containing a flexible print circuit bonding structure along the cross section lines A-A′ and B-B′ of FIG. 1 according to an embodiment of the invention;

FIG. 3 shows an illustrative top view of a portion of an electronic device containing a flexible print circuit bonding structure according to another embodiment of the invention;

FIG. 4 shows an illustrative cross section of a portion of an electronic device containing a flexible print circuit bonding structure along the cross section lines A-A′ and B-B′ of FIG. 3 according to an embodiment of the invention;

FIG. 5 shows an illustrative top view of a portion of an electronic device containing a flexible print circuit bonding structure according to another embodiment of the invention;

FIG. 6 shows an illustrative cross section of a portion of an electronic device containing a flexible print circuit bonding structure along the cross section line C-C′ of FIG. 5 according to an embodiment of the invention;

FIG. 7 shows an illustrative top view of a portion of an electronic device containing a flexible print circuit bonding structure according to another embodiment of the invention; and

FIG. 8 shows an illustrative cross section of a portion of an electronic device containing a flexible print circuit bonding structure along the cross section line D-D′ of FIG. 7 according to an embodiment of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

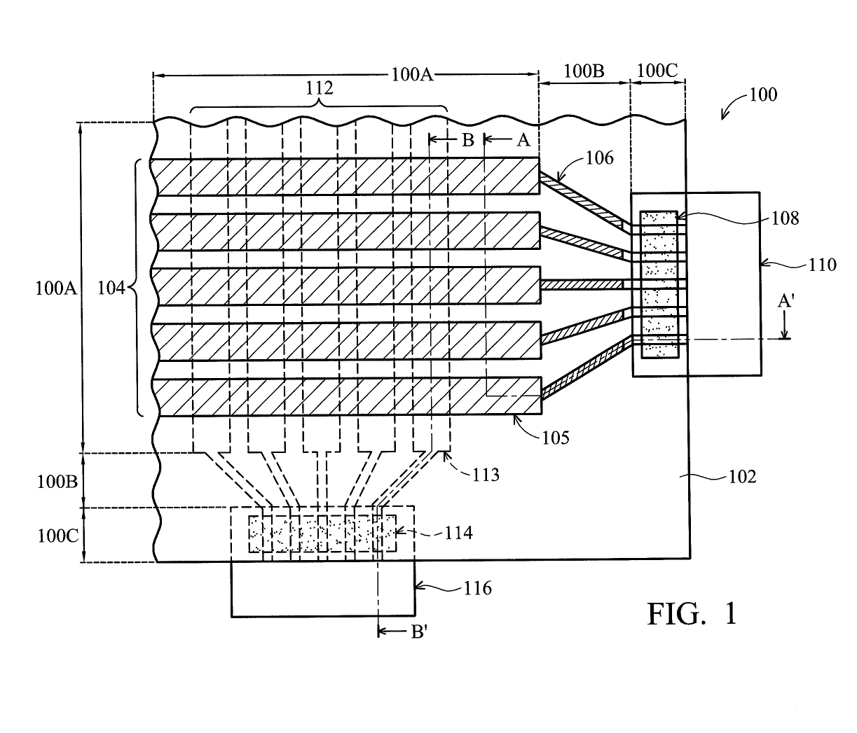

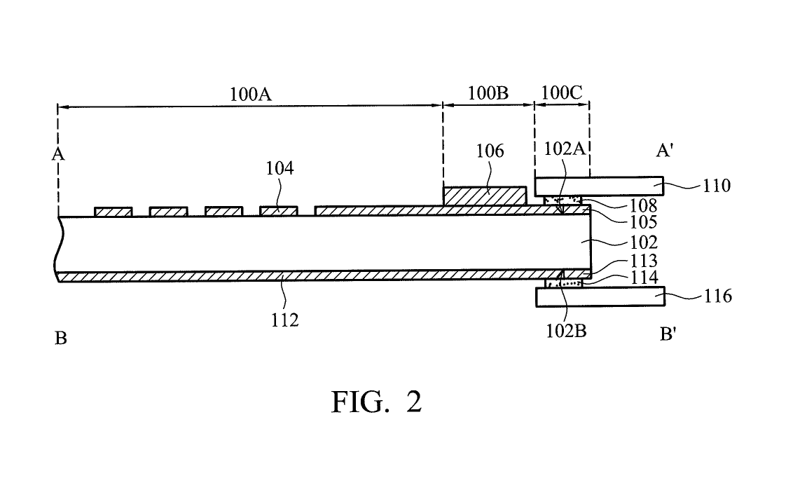

FIG. 1 shows a top view of a portion of an electronic device 100 containing a flexible print circuit bonding structure according to an embodiment of the invention, and FIG. 2 shows a cross section of a portion of the electronic device 100 containing the flexible print circuit bonding structure along the cross section lines A-A′ and B-B′ of FIG. 1 according to an embodiment of the invention. In an embodiment, the electronic device 100 has a viewing area 100A, a tracing area 100B and a bonding area 100C, wherein the tracing area 100B is disposed between the viewing area 100A and the bonding area 100C. A plurality of touch sensing electrodes 104 and 112 is disposed at the viewing area 100A, thus the viewing area 100A is also referred to as an active area. In one embodiment, the touch sensing electrodes 104 may be a plurality of strip-shaped touch sensing electrodes extending along a first direction (for example an X-axis direction) and the touch sensing electrodes 112 may be a plurality of strip-shaped touch sensing electrodes extending along a second direction (for example a Y-axis direction). In other embodiments, the touch sensing electrodes 104 and 112 may have other shapes and other arrangements.

In the embodiment, the touch sensing electrodes 104 and 112 are formed from a first transparent conductive layer 105 and a second transparent conductive layer 113, respectively. The first transparent conductive layer 105 is formed on a first surface 102A of a substrate 102 and the second transparent conductive layer 113 is formed on a second surface 102B of the substrate 102. The materials of the first transparent conductive layer 105 and the second transparent conductive layer 113 may be indium tin oxide (ITO) or other transparent conductive materials. The substrate 102 may be a transparent glass substrate or plastic substrate. The first transparent conductive layer 105 and the second transparent conductive layer 113 are not only used to form the touch sensing electrodes 104 and 112 respectively at the viewing area 100A, but they also extend to the tracing area 100B and the bonding area 100C to form a plurality of traces.

A metal trace layer 106 is formed on the first transparent conductive layer 105 at the tracing area 100B, but does not extend to the bonding area 100C. The metal trace layer 106 is electrically connected to the touch sensing electrodes 104 through the first transparent conductive layer 105 at the tracing area 100B. In an embodiment, the metal trace layer 106 is formed by a printing process, such as a relief printing or a gravure printing technology or a transfer printing technology. The material of the metal trace layer 106 formed by a printing process is a printing metal conductive glue, for example a silver glue or a gold glue. The metal trace layer 106 formed by the printing process has a thickness of about 5 μm to about 15 μm. In another embodiment, the metal trace layer 106 can be formed by a sputtering process. The metal trace layer 106 formed by the sputtering process has a thickness of less than 1 μm. The material of the metal trace layer 106 formed by the sputtering process is for example Mo, Al, or a combination thereof.

A first anisotropic conductive film (ACF) 108 is directly bonded on a surface of the first transparent conductive layer 105 at the bonding area 100C. A first flexible print circuit (FPC) 110 is bonded on the first anisotropic conductive film (ACF) 108. Moreover, a second anisotropic conductive film (ACF) 114 is directly bonded on a surface of the second transparent conductive layer 113 at the bonding area 100C. A second flexible print circuit (FPC) 116 is bonded under the second anisotropic conductive film (ACF) 114 to complete a flexible print circuit bonding structure of the embodiment.

Although the cross section of FIG. 2 shows the first anisotropic conductive film (ACF) 108 aligned with the second anisotropic conductive film (ACF) 114, and the first flexible print circuit (FPC) 110 aligned with the second flexible print circuit (FPC) 116. However, actually, the first anisotropic conductive film (ACF) 108 is not aligned with the second anisotropic conductive film (ACF) 114, and the first flexible print circuit (FPC) 110 is not aligned with the second flexible print circuit (FPC) 116. The alignment shown in FIG. 2 is produced by the first surface 102A and the second surface 102B of the substrate 102 respectively showing the cross section lines A-A′ and B-B′ of FIG. 1.

Furthermore, in the embodiment, compared with a tracing distance from the touch sensing electrodes 104 to the bonding area 100C used for traces, a tracing distance from the touch sensing electrodes 112 to the bonding area 100C used for traces is shorter. Thus, there is no need to dispose a metal trace layer on the surface of the second transparent conductive layer 113 at the tracing area 100B.

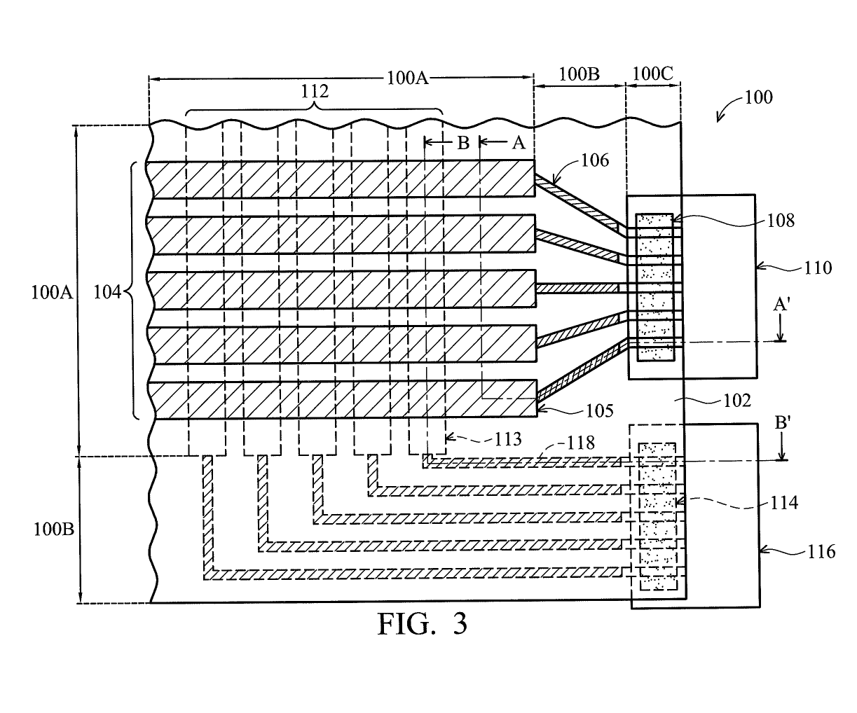

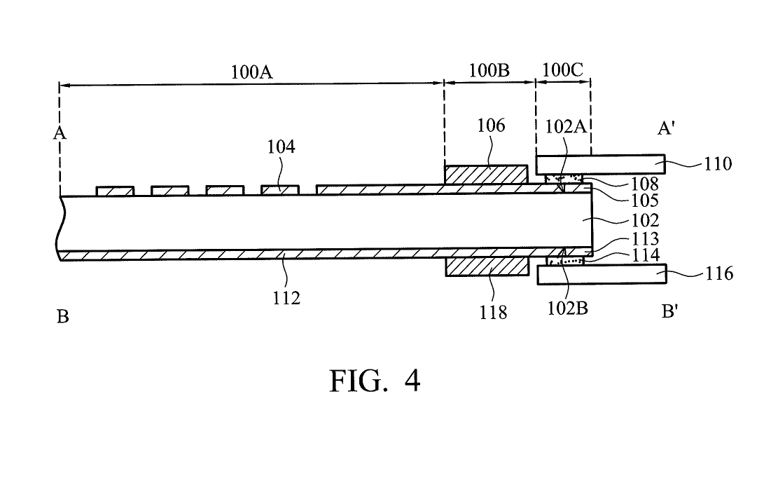

FIG. 3 shows a top view of a portion of an electronic device 100 containing a flexible print circuit bonding structure according to another embodiment of the invention, and FIG. 4 shows a cross section of a portion of the electronic device 100 containing the flexible print circuit bonding structure along the cross section lines A-A′ and B-B′ of FIG. 3 according to another embodiment of the invention. The difference between the embodiment of FIGS. 1-2 and the embodiment of FIGS. 3-4 is that the second anisotropic conductive film (ACF) 114 and the second flexible print circuit (FPC) 116 disposed on the second surface 102B of the substrate 102 and the first anisotropic conductive film (ACF) 108 and the first flexible print circuit (FPC) 110 disposed on the first surface 102A of the substrate 102 are located at the same side of the substrate 102. Therefore, compared with the embodiment of FIGS. 1-2, the tracing distance from the touch sensing electrodes 112 to the bonding area 100C used for traces of the embodiment of FIGS. 3-4 is longer. It needs a second metal trace layer 118 to be disposed on the surface of the second transparent conductive layer 113 at the tracing area 100B to reduce the resistance of the traces at the tracing area 100B on the second surface 102B of the substrate 102 and help the electrical conduction from the touch sensing electrodes 112 to the second anisotropic conductive film (ACF) 114 at the bonding area 100C.

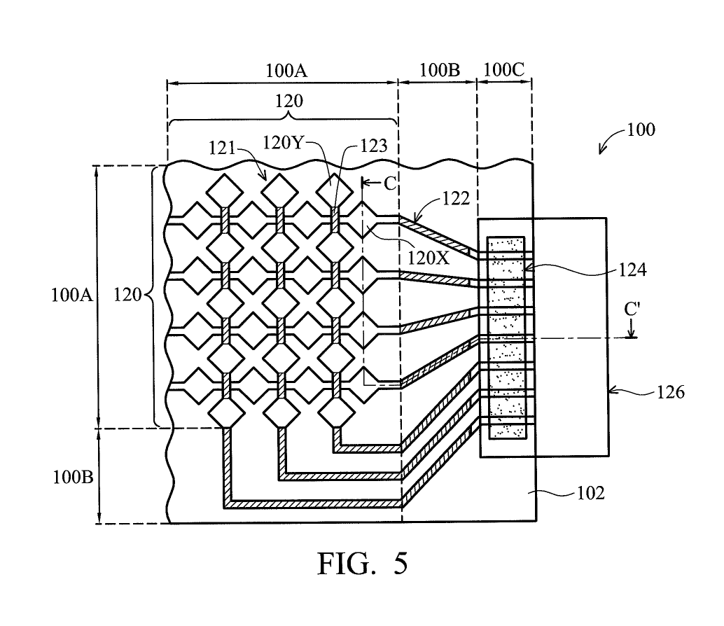

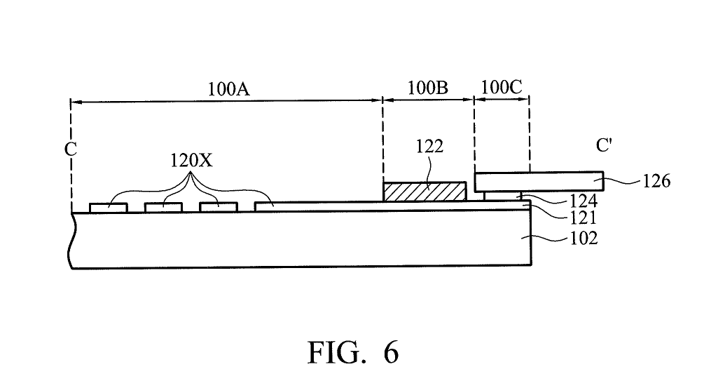

FIG. 5 shows a top view of a portion of an electronic device 100 containing a flexible print circuit bonding structure according to another embodiment of the invention, and FIG. 6 shows a cross section of a portion of the electronic device 100 containing the flexible print circuit bonding structure along the cross section line C-C′ of FIG. 5 according to an embodiment of the invention. In the embodiment, a plurality of touch sensing electrodes 120 is disposed at the viewing area 100A. The touch sensing electrodes 120 include a plurality of rhombus-shaped touch sensing electrodes 120X extending along a first direction (for example an X-axis direction) and the touch sensing electrodes 120X are connected with each other. The touch sensing electrodes 120 further include a plurality of rhombus-shaped touch sensing electrodes 120Y extending along a second direction (for example a Y-axis direction) and the touch sensing electrodes 120Y are separated from each other. The touch sensing electrodes 120Y are electrically connected with each other through a bridge structure 123. The bridge structure 123 may be formed from ITO or a metal material. In other embodiments, the touch sensing electrodes 120 may have other shapes and other arrangements.

In the embodiment, the touch sensing electrodes 120 are formed from the same layer of a transparent conductive layer 121. The transparent conductive layer 121 is formed on the substrate 102. The material of the transparent conductive layer 121 may be ITO or another transparent conductive material. The substrate 102 may be a transparent glass substrate or plastic substrate. The transparent conductive layer 121 is not only used to form the touch sensing electrodes 120 at the viewing area 100A, but also extends to the tracing area 100B and the bonding area 100C to form a plurality of traces.

A metal trace layer 122 is formed on the transparent conductive layer 121 at the tracing area 100B, but does not extend to the bonding area 100C. The metal trace layer 122 is electrically connected to the touch sensing electrodes 120 through the transparent conductive layer 121. In an embodiment, the metal trace layer 122 is formed by a printing process. The material of the metal trace layer 122 formed by the printing process is a printing metal conductive glue, for example a silver glue or a gold glue. The metal trace layer 122 formed by the printing process has a thickness of about 5 μm to about 15 μm. In another embodiment, the metal trace layer 122 can be formed by a sputtering process. The metal trace layer 122 formed by the sputtering process has a thickness of less than 1 μm. The material of the metal trace layer 122 formed by the sputtering process is for example Mo, Al, or a combination thereof. An anisotropic conductive film (ACF) 124 is directly bonded on a surface of the transparent conductive layer 121 at the bonding area 100C. Then, a flexible print circuit (FPC) 126 is bonded on the anisotropic conductive film (ACF) 124 to complete a flexible print circuit bonding structure of the embodiment.

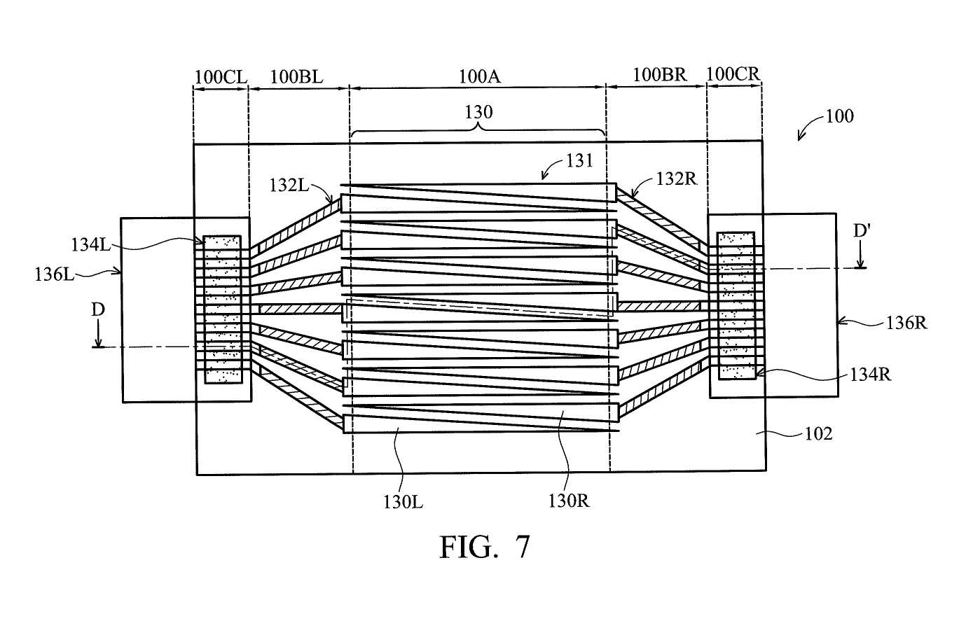

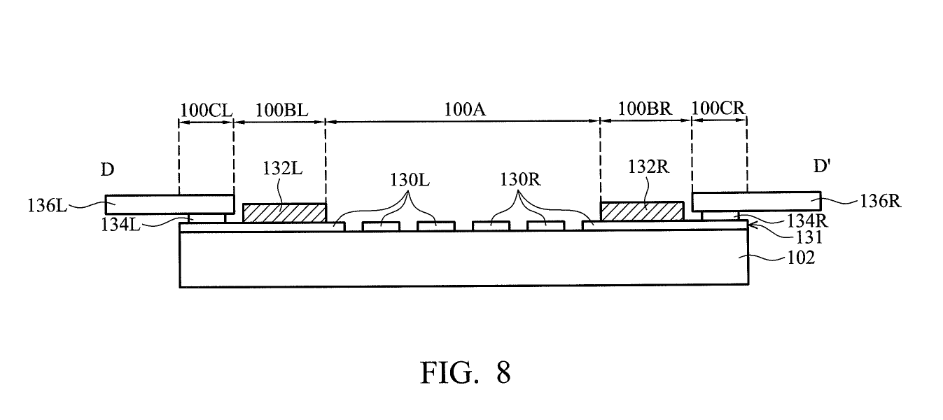

FIG. 7 shows a top view of a portion of an electronic device 100 containing a flexible print circuit bonding structure according to another embodiment of the invention, and FIG. 8 shows a cross section of a portion of the electronic device 100 containing the flexible print circuit bonding structure along the cross section line D-D′ of FIG. 7 according to an embodiment of the invention. In the embodiment, the electronic device 100 has a viewing area 100A, a first tracing area 100BR and a second tracing area 100BL respectively disposed on the right side and left side of the viewing area 100A, and a first bonding area 100CR and a second bonding area 100CL respectively disposed on the right side of the first tracing area 100BR and the left side of the second tracing area 100BL.

In the embodiment, a plurality of touch sensing electrodes 130 is disposed at the viewing area 100A. The touch sensing electrodes 130 include a plurality of strip-shaped touch sensing electrodes 130R extending along a first direction (for example an X-axis direction) and the touch sensing electrodes 130R have a width gradually increasing along the first direction. The touch sensing electrodes 130 further include a plurality of strip-shaped touch sensing electrodes 130L extending along the first direction (for example an X-axis direction) and the touch sensing electrodes 130L have a width gradually decreasing along the first direction. The touch sensing electrodes 130 are formed from the same layer of a transparent conductive layer 131. The transparent conductive layer 131 is formed on the substrate 102. The material of the transparent conductive layer 131 may be ITO or another transparent conductive material. The substrate 102 may be a transparent glass substrate or a plastic substrate. The transparent conductive layer 131 is not only used to form the touch sensing electrodes 130 at the viewing area 100A, but it also extends to the first tracing area 100BR, the second tracing area 100BL, the first bonding area 100CR and the second bonding area 100CL to form a plurality of traces.

A first metal trace layer 132R is formed on the transparent conductive layer 131 at the first tracing area 100BR, but does not extend to the first bonding area 100CR. The first metal trace layer 132R is electrically connected to the touch sensing electrodes 130R through the transparent conductive layer 131. A second metal trace layer 132L is formed on the transparent conductive layer 131 at the second tracing area 100BL, but does not extend to the second bonding area 100CL. The second metal trace layer 132L is electrically connected to the touch sensing electrodes 130L through the transparent conductive layer 131.

In an embodiment, the first metal trace layer 132R and the second metal trace layer 132L are formed by a printing process. The materials of the first metal trace layer 132R and the second metal trace layer 132L are a printing metal conductive glue, for example a silver glue or a gold glue. The first metal trace layer 132R and the second metal trace layer 132L formed by the printing process have a thickness of about 5 μm to about 15 μm. In another embodiment, the first metal trace layer 132R and the second metal trace layer 132L may be formed by a sputtering process. The first metal trace layer 132R and the second metal trace layer 132L formed by the sputtering process have a thickness of less than 1 μm. The materials of the first metal trace layer 132R and the second metal trace layer 132L formed by the sputtering process are for example Mo, Al, or a combination thereof.

A first anisotropic conductive film (ACF) 134R is directly bonded on a surface of the transparent conductive layer 131 at the first bonding area 100CR. Then, a first flexible print circuit (FPC) 136R is bonded on the first anisotropic conductive film (ACF) 134R. Furthermore, a second anisotropic conductive film (ACF) 134L is directly bonded on a surface of the transparent conductive layer 131 at the second bonding area 100CL. Then, a second flexible print circuit (FPC) 136L is bonded on the second anisotropic conductive film (ACF) 134L to complete a flexible print circuit bonding structure of the embodiment.

According to the flexible print circuit bonding structures of an electronic device provided from the embodiments of the invention, the metal trace layer electrically connecting to the electronic elements (such as the touch sensing electrodes) at the viewing area is only disposed at the tracing area, but does not extend to the bonding area. Therefore, the anisotropic conductive film (ACF) used for bonding with the flexible print circuit (FPC) directly contacts the transparent conductive layer at the bonding area. Compared with the conventional flexible print circuit bonding structures of electronic devices, the flexible print circuit bonding structures of the embodiments of the invention can prevent the flexible print circuit (FPC) from delaminating. Thus, the reliability of the flexible print circuit bonding structures of an electronic device is enhanced.

Moreover, compared with the conventional flexible print circuit bonding structures of electronic devices, the flexible print circuit bonding structures of the embodiments of the invention are more suitable for the metal trace layer fabricated by a printing process. Thus, the material and the fabrication cost of the metal trace layer is reduced.

While the invention has been described by way of example and in terms of the preferred embodiments, it is to be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A flexible print circuit bonding structure of an electronic device, the electronic device having a viewing area, a tracing area and a bonding area, wherein the tracing area is disposed between the viewing area and the bonding area, the flexible print circuit bonding structure comprising:
a substrate, having a first surface and a second surface opposite to the first surface;
a first transparent conductive layer disposed on the first surface of the substrate and extending from the tracing area to the bonding area;
a first metal trace layer disposed on the first transparent conductive layer at the tracing area, but not extending to the bonding area;
a first anisotropic conductive film disposed on the first transparent conductive layer at the bonding area, wherein the first anisotropic conductive film directly contacts with the first transparent conductive layer; and
a first flexible print circuit bonded to the first anisotropic conductive film.

2. The flexible print circuit bonding structure of claim 1, wherein the material of the first metal trace layer comprises a printing metal conductive glue and the first metal trace layer has a thickness of 5 μm to 15 μm.

3. The flexible print circuit bonding structure of claim 1, further comprising a second transparent conductive layer disposed on the second surface of the substrate and extending from the tracing area to the bonding area.

4. The flexible print circuit bonding structure of claim 3, further comprising:
a second anisotropic conductive film disposed on the second transparent conductive layer at the bonding area, wherein the second anisotropic conductive film directly contacts with the first transparent conductive layer; and
a second flexible print circuit bonded to the second anisotropic conductive film.

5. The flexible print circuit bonding structure of claim 4, further comprising a second metal trace layer disposed on the second transparent conductive layer at the tracing area, but not extending to the bonding area.

6. The flexible print circuit bonding structure of claim 3, wherein the first transparent conductive layer and the second transparent conductive layer are further disposed respectively on the first surface and the second surface of the substrate in the viewing area, the first transparent conductive layer comprises a plurality of touch sensing electrodes extending along a first direction, and the second transparent conductive layer comprises a plurality of touch sensing electrodes extending along a second direction, wherein the first direction is perpendicular to the second direction.

7. The flexible print circuit bonding structure of claim 1, wherein the first transparent conductive layer is further disposed on the substrate in the viewing area, and the first transparent conductive layer comprises a plurality of touch sensing electrodes extending along a first direction and a plurality of touch sensing electrodes extending along a second direction, wherein the first direction is perpendicular to the second direction.

8. The flexible print circuit bonding structure of claim 1, wherein the tracing area comprises a first tracing area and a second tracing area disposed respectively at two sides of the viewing area, and the bonding area comprises a first bonding area and a second bonding area respectively disposed at one side of the first tracing area and one side of the second tracing area.

9. The flexible print circuit bonding structure of claim 8, wherein the first metal trace layer is disposed at the first tracing area and the first anisotropic conductive film is disposed at the first bonding area, with the flexible print circuit bonding structure further comprising:
a second metal trace layer disposed on the first transparent conductive layer at the second tracing area, but not extending to the second bonding area;
a second anisotropic conductive film disposed on the first transparent conductive layer at the second bonding area, wherein the second anisotropic conductive film directly contacts with the first transparent conductive layer; and
a second flexible print circuit bonded to the second anisotropic conductive film.

10. The flexible print circuit bonding structure of claim 9, wherein the first transparent conductive layer is further disposed on the substrate in the viewing area, the first transparent conductive layer comprises a plurality of first touch sensing electrodes extending along a first direction and a plurality of second touch sensing electrodes extending along the first direction, wherein the first touch sensing electrodes have a width gradually increased along the first direction and the second touch sensing electrodes have a width gradually decreased along the first direction, the first touch sensing electrodes are electrically connected to the first metal trace layer and the second touch sensing electrodes are electrically connected to the second metal trace layer.
